(19) United States
(12) Patent Application Publication
(10) Pub. No.: US 2008/0073700 A1
(43) Pub. Date: Mar. 27, 2008

(54) MANUFACTURING METHOD OF FLASH MEMORY DEVICE

(76) Inventor: Joo-Hyeon Lee, Seoul (KR)

Correspondence Address: SHERR & NOURSE, PLLC, 620 HERNDON PARKWAY, SUITE 200, HERNDON, VA, 20170, US

(21) Appl. No.: 11/849,755

(22) Filed: Sep. 4, 2007

(30) Foreign Application Priority Data
Sep. 22, 2006 (KR) 10-2006-0092092

(51) Int. Cl. H01L 29/788; H01L 21/336

(52) U.S. Cl. 257/321; 438/261; 257/E29.3; 257/E21.422

(57) ABSTRACT

A method for manufacturing a flash memory device includes: forming a floating gate on a tunnel oxide film formed on a semiconductor substrate; forming an ONO film on the floating gate; performing a well implant process to form a well on the semiconductor substrate; and performing an ashing process and a cleaning process using at least two of H₂SO₄, H₂O₂, HF, H₂O, and O₃. As a result, roughness is not generated on the upper surface of the ONO film which tends to cause data retention failures of the flash memory device during a high temperature operating life (HTOL) testing process, making it possible to improve the reliability of the flash memory device.

This application claims the benefit under 35 U.S.C. § 119 of Korean Patent Application No. 10-2006-0092092, filed on Sep. 22, 2006, which is hereby incorporated by reference in its entirety.

### BACKGROUND

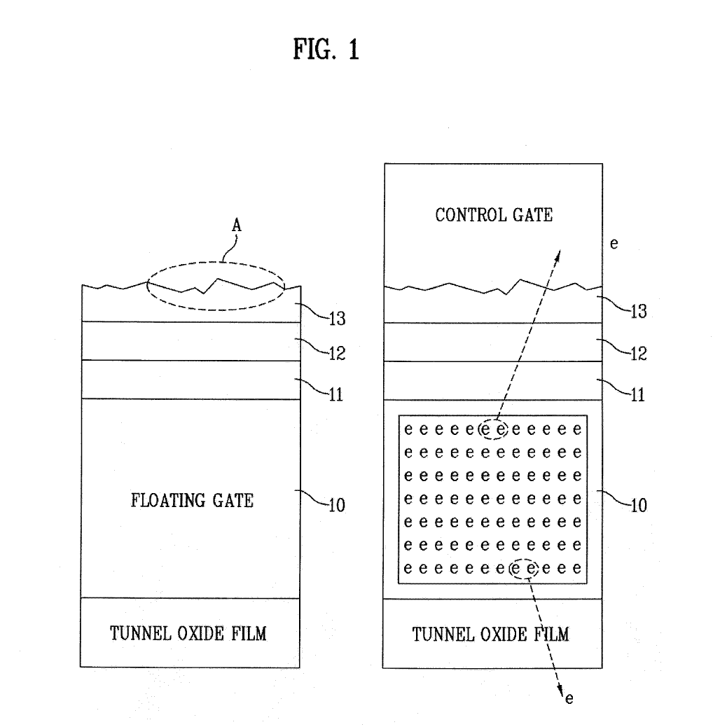

Generally, a flash memory device has a structure that includes an oxide-nitride-oxide (ONO) film between a floating gate and a control gate. One method of forming the ONO film, for example, forms a floating gate 10 using polysilicon and then sequentially deposits and forms a silicon oxide film 11, a silicon nitride film 12, and a silicon oxide film 13 on the floating gate 10. Then an etching process and a cleaning process is performed for forming the ONO film formed of the silicon oxide film 11, the silicon nitride film 12, and the silicon oxide film 13, as shown in example FIG. 1.

Next, the method performs an implantation process for forming a well area and can further perform an ashing process and a cleaning process as part of the implantation process. This further cleaning process uses a cleaning solution that is generally a mixture of H₂SO₄ and H₂O₂ and uses an ashing solution that is a mixture of NH₄OH, H₂O₂ and H₂O in order to remove any remaining photoresist and polymer, etc. When using the ashing solution that is a mixture of NH₄OH, H₂O₂ and H₂O, surface roughness is typically generated on the ONO film as shown in portion A of example FIG. 1 and if the generated surface roughness is locally severe, a data retention failure can be caused in a high temperature operating life (HTOL) testing process in which baking is performed at 250° C. for 168 hours after a program.

### SUMMARY

Embodiments relate to a method for manufacturing a flash memory device that includes: forming a floating gate on a tunnel oxide film formed on a semiconductor substrate; forming an ONO film on the floating gate; performing a well implant process to form a well on the semiconductor substrate; and performing an ashing process and a cleaning process using at least two of H₂SO₄, H₂O₂, HF, H₂O, and O₃.

Embodiments relate to a flash memory device that includes a floating gate on a tunnel oxide film formed on a semiconductor substrate; an ONO film on the floating gate, wherein an upper surface of the ONO film is smooth; and a well on the semiconductor substrate.

### DRAWINGS

Example FIG. 1 is an exemplification view showing surface roughness generated in an ONO film of a flash memory device.

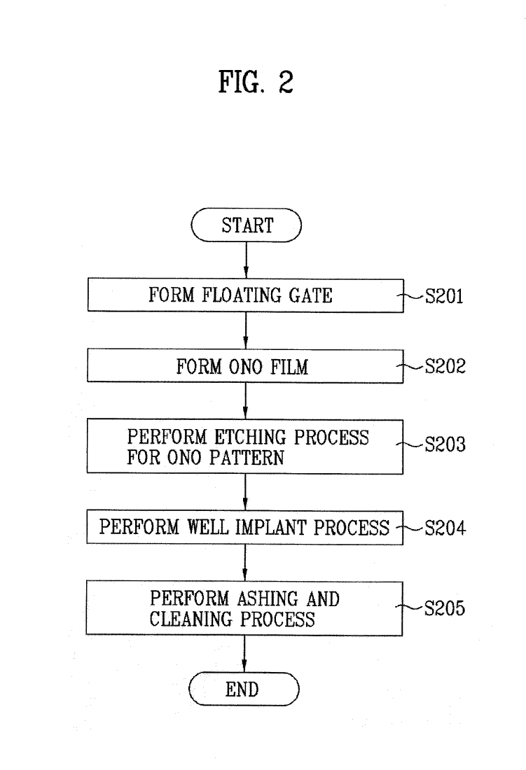

Example FIG. 2 is a flow view showing a manufacturing method of a flash memory device according to the embodiments described herein.

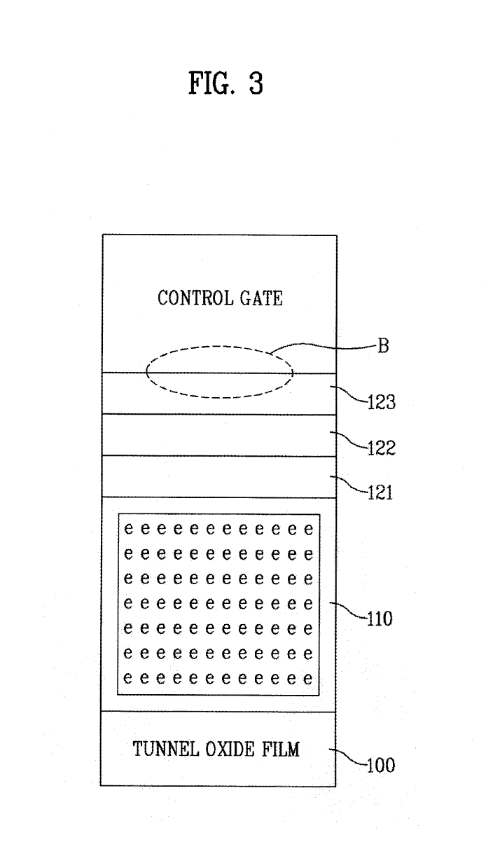

Example FIG. 3 is a cross-sectional view of the manufacturing method of the flash memory device according to the embodiments described herein.

### DESCRIPTION

Example FIG. 2 is a flow view showing a manufacturing method of a flash memory device according to the embodiments and example FIG. 3 is a cross-sectional view of the flash memory device manufactured according to the embodiments.

As shown in example FIG. 2, a manufacturing method of a flash memory device according to the embodiments first forms a floating gate 110 on a tunnel oxide film 100 formed on a semiconductor substrate (S201).

In order to form the floating gate 110, a polysilicon film is formed on the tunnel oxide film 100 and an etching process is performed using a photoresist pattern (not shown) for KrF for forming the floating gate 110 in a state having a bottom antireflective coating (BARC). Herein, the etching process for forming the floating gate 110 can perform an RIE manner applying power of approximately 500 W to approximately 1000 W at atmospheric pressure of approximately 50 mT to approximately 80 mT and using CF₄ of approximately 60 sccm to approximately 100 sccm, Ar of approximately 100 sccm to approximately 150 sccm, and O₂ of approximately 5 sccm to approximately 15 sccm for approximately 30 to approximately 60 seconds.

After forming the floating gate 110, a lower oxide film 121 of SiO₂, a nitride film 122 of SiN, and an upper oxide film 123 of a silicon oxide film are formed on the floating gate 110 (S202).

An etching process is then performed on the ONO film so formed, that is, the lower oxide film 121, the nitride film 122 of SiN and the upper oxide film 123 for forming an ONO pattern provided on the floating gate 110 (S203). Herein, the etching process for forming the ONO pattern on the floating gate 110 can be performed using an isotropic RIE or an isotropic plasma etching process.

Next, a well implant process for forming a well is performed by implanting an N type dopant or a P type dopant on the semiconductor substrate including the ONO pattern and the floating gate 110 (S204). The well implant process can form a predetermined photoresist pattern on the semiconductor substrate, for example, it can form the photoresist pattern (not shown) for KrF, or form an N-well by implanting the N type dopant, that is, Phosphorus (P) or Arsenic (As), etc., when forming the N-well, or form a P-well by implanting the P type dopant, that is, Boron (B), etc., when forming the P-well. After forming the well implant process, an ashing process and a cleaning process for removing the photoresist pattern such as the photoresist pattern for KrF for the well implant process are performed (S205). After performing the ashing and cleaning processes according to the present invention, a general process for forming a control gate is performed.

In the ashing and cleaning processes according to the embodiments described herein, the ashing process is first performed using an example ashing solution mixture having H₂SO₄ and H₂O₂ at a ratio of approximately 1:1 to approximately 1:6 and the cleaning process is then performed using a cleaning solution mixture containing HF and H₂O₂. The reason why the cleaning solution containing HF and H₂O₂ is used is to avoid generating the surface roughness of region A shown in example FIG. 1 caused by using a cleaning solution mixing NH₄OH and H₂O₂ at a constant ratio using DI water as main component.

Therefore, the embodiments described herein use HF instead of NH₄OH to remove a polymer and any remaining photoresist material. The embodiments may also use a mixture containing HF and O₃ as cleaning solution.

Specifically, when using the HF instead of NH₄OH, a mixing ratio of HF:H₂O₂:H₂O can be set to approximately 1:1:1 to approximately 1:1:20 and an etch rate by the cleaning solution of HF and H₂O₂ or HF and O₃ can be controlled according to the concentration of HF aqueous solution, wherein the concentration of HF aqueous solution can be set to approximately 10:1 to approximately 1000:1.

Also, when selectively using the cleaning solution containing HF and O₃, the concentration of O₃ can be set to approximately 5 ppm to approximately 30 ppm.

Therefore, since the embodiments perform a more uniform etching as compared to the cleaning solution containing NH₄OH, a conventional ashing process can be omitted and as shown in example FIG. 3, the roughness is not generated on the surface of the upper oxide film 123 (portion B) so that data retention failures of the flash memory device do not occur during the high temperature operating life (HTOL) testing process, making it possible to improve the reliability of the flash memory device.

The embodiments as described above do not generate roughness on the upper surface of the ONO film so that data retention failures of the flash memory device do not occur during the high temperature operating life (HTOL) testing process, making it possible to improve the reliability of the flash memory device.

What is claimed is:

1. A method of manufacturing a flash memory device comprising:
forming a floating gate on a tunnel oxide film formed on a semiconductor substrate;
forming an ONO film on the floating gate;
forming a well on the semiconductor substrate; and
performing an ashing process and a cleaning process using at least two of H₂SO₄, H₂O₂, HF, H₂O, and O₃.

2. The method of claim 1, wherein forming a well further includes:
performing a well implant process.

3. The method of claim 1, wherein forming the floating gate is performed using a reactive ion etching process.

4. The method of claim 3, wherein the reactive ion etching process includes applying power between approximately 500 W to approximately 1000 W.

5. The method of claim 3, wherein the reactive ion etching process is performed at atmospheric pressure between approximately 50 mT to 80 mT.

6. The method of claim 3, wherein the reactive ion etching process uses CF₄ between approximately 60 sccm to approximately 100 sccm.

7. The method of claim 3, wherein the reactive ion etching process uses Ar between approximately 100 sccm to approximately 150 sccm.

8. The method of claim 3, wherein the reactive ion etching process uses O₂ between approximately 5 sccm to approximately 15 sccm.

9. The method of claim 3, wherein the reactive ion etching process includes forming a bottom antireflective coating (BARC).

10. The method of claim 3, wherein the reactive ion etching process includes forming a photoresist pattern.

11. The method of claim 10, wherein the photoresist pattern is a KrF photoresist pattern patterned using a photoresist for KrF.

12. The method of claim 1, wherein performing the ashing and cleaning processes comprises performing the ashing process using an ashing solution mixture comprising H₂SO₄ and H₂O₂ at approximately 1:1 to approximately 1:6.

13. The method of claim 1, wherein performing the ashing and cleaning processes comprises performing the cleaning process using a cleaning solution comprising HF, H₂O₂ and H₂O at approximately 1:1:1 to approximately 1:1:20.

14. The method of claim 1, wherein performing the ashing and cleaning process comprises performing the ashing process using an ashing solution mixture comprising H₂SO₄ and H₂O₂ at approximately 1:1 to approximately 1:6; and performing the cleaning process using cleaning solution containing HF and O₃.

15. The method of claim 1, wherein performing the ashing and cleaning processes includes performing the cleaning process using cleaning solution containing HF and O₃.

16. The method of claim 14, wherein the concentration of O₃ is between approximately 5 ppm to approximately 30 ppm.

17. The method of claim 15, wherein the concentration of O₃ is between approximately 5 ppm to approximately 30 ppm.

18. The method according to claim 13, wherein a concentration of HF aqueous solution is between approximately 10:1 to approximately 1000:1.

19. The method according to claim 14, wherein a concentration of HF aqueous solution is between approximately 10:1 to approximately 1000:1.

20. A flash memory device comprising:
a floating gate on a tunnel oxide film formed on a semiconductor substrate;
an ONO film on the floating gate, wherein an upper surface of the ONO film is smooth; and
a well on the semiconductor substrate.
